(19) United States
(12) Patent Application Publication
(10) Pub. No.: US 2002/0185168 A1
(43) Pub. Date: Dec. 12, 2002

(54) Thermoelectric vaporizer for the efficient generation of electricity thermoelectrically and for the simultaneous vaporization of a cryogen

(76) Inventor: Robert Daniel Hunt, Pass Christian, MS (US)

Correspondence Address: ROBERT DANIEL HUNT, 23707 REDFISH LANE, PASS CHRISTIAN, MS, 39571, US

(21) Appl. No.: 09/877,781

(22) Filed: Jun. 11, 2001

(51) Int. Cl. H01L 35/00

(52) U.S. Cl. 136/205; 136/236.1; 136/206; 136/208

(57) ABSTRACT

The present invention incorporates the generation of electricity with the vaporization of a cryogen such that all of the available heat is beneficially used. The heat is either converted to electricity thermoelectrically or the heat is absorbed by the cryogen to vaporize the cryogen into cryogenic vapor and to increase the internal energy of the energetic cryogenic vapor, which is capable of performing work.

### CROSS REFERENCE TO RELATED APPLICATIONS

Related U.S. patent applications by the Present Applicant, Robert D. Hunt, Customer Number 27531, titled, “Cryogen Production Via a Cryogenic Vapor Driven Power Piston for use in a Cryogenic Vapor Powered Vehicle with Rotary Vane Motors Attached to the Axles of the Vehicle next to the Vehicle's Four Wheels, Using a Heat Source such as Solar Heat, Heat of Compression (Heat Pump or Air Compressor, etc.) or Heat of Friction (as Formed by an Electric Generator) or Chemical Heat, or Heat Formed by Electrical Resistance, Heat of Combustion, etc. to Generate High-Pressure, High-Kinetic Energy Cryogenic Vapor”; and, titled, “Solid Oxide or Solid Acid High-Temperature Steam Electrolyzer Constructed in Alternating Layers of P-Type, N-Type, and Solid Oxide or Solid Acid Materials for the Self-Generation of Electricity Thermoelectrically for Electrolysis of High-Temperature Steam into Hydrogen and Oxygen”; and, titled “Cryogen Production and Cryogenic Heating and Cooling Device Constructed Therefrom”; and, titled, “Method of Cryogen Production and Thermoelectric Solid-State Electric Power Generation whereby the Thermal Energy of the Atmosphere is Directly Converted to Electrical Power and whereby the Thermal Energy of the Atmosphere is used to Produce High-Energy Cryogenic Vapor Capable of Performing Substantial Work and Pure Water is Produced from Water Vapor in the Atmosphere”

### BACKGROUND OF INVENTION

This invention relates to the production of electricity by energy conversion of heat to electricity thermoelectrically by the use of the Peltier effect or the converse, the Seebeck effect. Hot and cold junctions connect dissimilar metals in a closed circuit and the EMF develops current in the circuit in a measure related to the temperature difference and rate of heat input or output.

The generation of electricity thermoelectrically has been inefficient and therefore not cost effective, with an efficiency generally near five percent (5%) of heat being transformed into electricity. One of the major causes cited for the low efficiency is conductivity of heat through the p-type and n-type materials used. As a result semiconductor materials are often used in the construction of thermoelectric devices to reduce the conduction of heat.

U.S. Pat. No. 6,199,317 titled “Cryogenic Thermoelectric Generator” by Volk teaches us that the production of electricity may be performed by use of a cryogenic thermoelectric solid state generator. Electricity may be produced using cryogenics as the cold source for the cold side of a thermoelectric device.

U.S. Pat. No. 5,288,336 “Thermoelectric Energy Conversion”, Strachan et al. teaches us that thermoelectric power generation may be accomplished by using p-type and n-type materials in alternating layers with a cold source on one side of the layers of material and a heat source on the opposite side of the layers of material with the heat being able to conduct through the layers of material parallel to the p/n junctions of the material and with an alternating current to prevent the formation of cold spots to generate electricity more efficiently, creating a solid-state generator.

U.S. Pat. No. 5,288,336 also teaches us that base metals, such as aluminum and nickel, with high electrical and thermal conductivity may be used to efficiently generate electricity thermoelectrically by use of fast cycling A. C. current to prevent cold spot formation. Also, micro-thin layers of p-type and n-type materials are used of such small thickness, 200 angstrom aluminum and 400 angstrom nickel, that the electrical conductivity is greatly increased relative to the thermal conductivity.

U.S. Pat. No. 5,288,336 claims an extremely high efficiency using micro-thin layers of alternating aluminum and nickel, conductive base materials, of in excess of 300 micro-volts per deg. C. with a net energy conversion efficiency well above 46% of that set by the Carnot Limit, but thermoelectric devices in general have a low efficiency (usually less than 10% conversion of heat to electricity) because much of the heat is thermally conducted across the materials used, becomes heat loss, and the heat is not converted to electricity.

Super-conducting materials of copper oxides which exhibit superconductivity at higher temperatures have resulted in less electrical resistance in thermoelectric devices.

Within the field of cryogenics a vaporizer is used to transfer heat to liquid cryogen in order to vaporize the cryogen into cryogenic vapor, the gaseous state. Heat is generally taken from the ambient temperature of the atmosphere, having a much higher temperature than the cryogen, defined as being below −150 C. However, other sources of heat may be used as the vaporizer is effectively a heat exchanger with a cryogen flowing through the vaporizer.

The present patent application serves to beneficially use the heat loss inherent in thermoelectric power generation due to thermal conduction to vaporize a cryogen and to thus improve on the process of the prior art patents in the efficient use of heat.

The Applicant has filed a pending U.S. patent application titled, “Cryogen Production Via a Cryogenic Vapor Driven Power Piston for use in a Cryogenic Vapor Powered Vehicle with Rotary Vane Motors Attached to the Axles of the Vehicle next to the Vehicle's Four Wheels, Using a Heat Source such as Solar Heat, Heat of Compression (Heat Pump or Air Compressor, etc.) or Heat of Friction (as Formed by an Electric Generator) or Chemical Heat, or Heat Formed by Electrical Resistance, Heat of Combustion, etc. to Generate High-Pressure, High-Kinetic Energy Cryogenic Vapor”.

The thermoelectric vaporizer that is the present invention of this patent application is used within the cryogenic vapor powered vehicle of the above co-pending patent application to generate electricity and to vaporize the cryogen produced and to perform work with the energetic cryogenic vapor, including the production of liquid cryogen from air in the atmosphere.

The present invention incorporates the generation of electricity with the vaporization of a cryogen such that all of the available heat is beneficially used. The heat is either converted to electricity thermoelectrically or the heat is absorbed by the cryogen to vaporize the cryogen into cryogenic vapor and to increase the internal energy of the cryogenic vapor formed.

The present invention beneficially and inventively uses the heat loss that conducts through the layers of materials used in thermoelectric power generation to vaporize a cryogen.

### SUMMARY OF INVENTION

The present invention forms a heat exchanger made of alternating layers of p-type and n-type materials that form a thermoelectric generator. The simplest form of the invention has a heat source on its exterior and a cryogen flowing through the heat exchanger, such that heat conducts through the layers of material. A portion of the heat is thermoelectrically transformed into electricity at the p/n junctions, and the remainder of the heat is absorbed by the cryogen that acts as a heat sink. The cryogen is vaporized by the heat it absorbs.

The materials used are highly conductive both electrically and thermally in order to facilitate the transfer of heat and electricity through the materials. The materials also are of a micro-thin thickness as to provide additional p/n junctions capable of transforming heat into electricity. An alternating A. C. current is also employed to prevent cold-spot formation within the layers and to generate A. C. power.

The vaporized cryogen becomes cryogenic vapor, having substantial kinetic energy, is capable of performing work, such as powering a rotary vane motor, bladeless turbine, gas expander, pistons, or other forms of mechanical drive.

### BRIEF DESCRIPTION OF DRAWINGS

FIG. 1. describes a thermoelectric cryogenic vaporizer made of alternating of p-type and n-type materials capable of generating electrical power as it simultaneously performs as a heat exchanger to vaporize a cryogen.

FIG. 2. describes a vacuum insulated thermoelectric generator and cryogenic vaporizer using p-type and n-type materials in alternating layers with the direction of heat flow parallel to the p/n junctions of the layers of material with a cryogen on one end of the layers of material and a heat source on the other end in alternation. An alternating current is also established.

FIG. 3. describes a vacuum insulated tubular thermoelectric device that acts both as a cryogenic heat exchanger (vaporizer) and acts as a solid-state electric generator.

FIG. 4. describes a thermoelectric cryogenic heat exchanger (vaporizer) using more than one heat source. The cryogen and heat sources are separated by layers of p-type and n-type materials to produce electricity. The atmosphere is the outer heat source and the inner heat source may be the heat of compression, solar heat, geothermal water, hot exhaust gases of combustion, or chemical heat, etc.

FIG. 5. describes a thermoelectric solar collector that is capable of vaporizing liquid air while it produces electricity. The apparatus may be located on the roof or other surfaces of a cryogenic vapor powered vehicle where sunlight may be concentrated. It also may be used to produce electricity and to vaporize a cryogen that forms cryogenic vapor capable of performing mechanical work at other sites such as a business or home.

### DETAILED DESCRIPTION

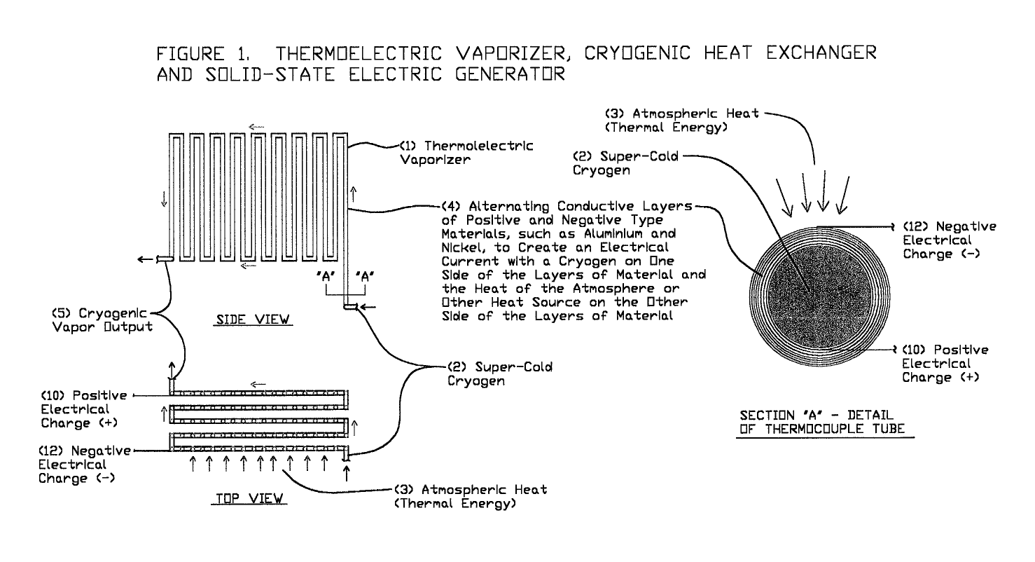

FIG. 1. describes a thermoelectric vaporizer (1) constructed of alternating layers of thermally and electrically conductive p-type and n-type materials (4) capable of generating electrical power as the thermoelectric vaporizer (1) simultaneously performs as a cryogenic heat exchanger. A super-cold cryogen (2) flows through the center of the thermoelectric vaporizer (1) that is tubular in shape and atmospheric heat (3) is on the outside of the tubes. The walls of the tubes are constructed in alternating layers of p-type and n-type materials (4). As heat (3) penetrates the layers of material (4), electricity is generated thermoelectrically by a portion of the heat (3) and a positive electrical charge (10) is generated and a negative electrical charge (12) is generated.

A portion of the heat (3) is not converted into electricity and conducts through the layers of materials (4) and is absorbed by the cryogen (2). The heat (3) absorbed by the cryogen (2) causes the cryogen to vaporize to form cryogenic vapor (5). The cryogenic vapor (5) exits the thermoelectric vaporizer (1).

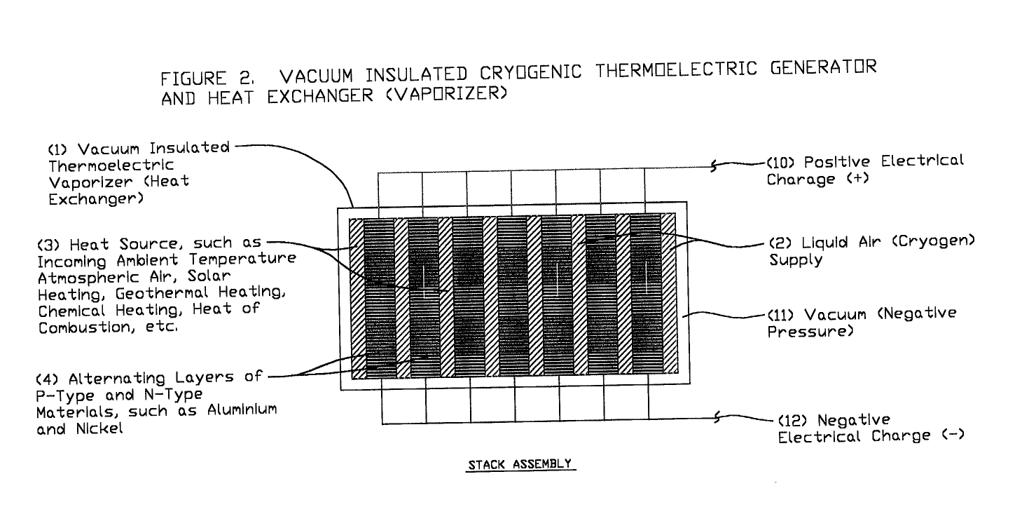

FIG. 2., the preferred embodiment of the invention, describes a vacuum insulated thermoelectric vaporizer (1 ) that performs as a solid-state electric generator and as a cryogenic heat exchanger to vaporize a cryogen (2). The thermoelectric vaporizer (1) is constructed of p-type and n-type materials (4) in alternating layers with the direction of heat flow parallel to the p/n junctions of the layers of material with a cryogen (2) on one end of the layers of material (4) and a heat source (3) on the other end of the layers of material (4). The thermoelectric vaporizer is constructed of alternating rectangular or square sections of a heat source (3) flowing through the vaporizer (1) then a stack of alternating layers of p-type and n-type materials separating the heat source (3) and the cryogen (2) flowing on the other side of the p/n materials (4). This arrangement is repeated: A heat source (3), a stack of layers of materials (4), cryogen (2), a stack of layers of materials (4), heat source (3), a stack of layers of materials (4), cryogen (2), a stack of layers of materials (4), heat source (3), a stack of layers of materials (4), cryogen. . . .

An alternating current is established within the stacks of layer of materials (4). A positive charge (10) is created and a negative charge (12) is also created.

The thermoelectric vaporizer (1) is rectangular or square in shape and is surrounded by vacuum insulation (11) that prevents the ambient temperature of the atmosphere from reaching the thermoelectric vaporizer (1).

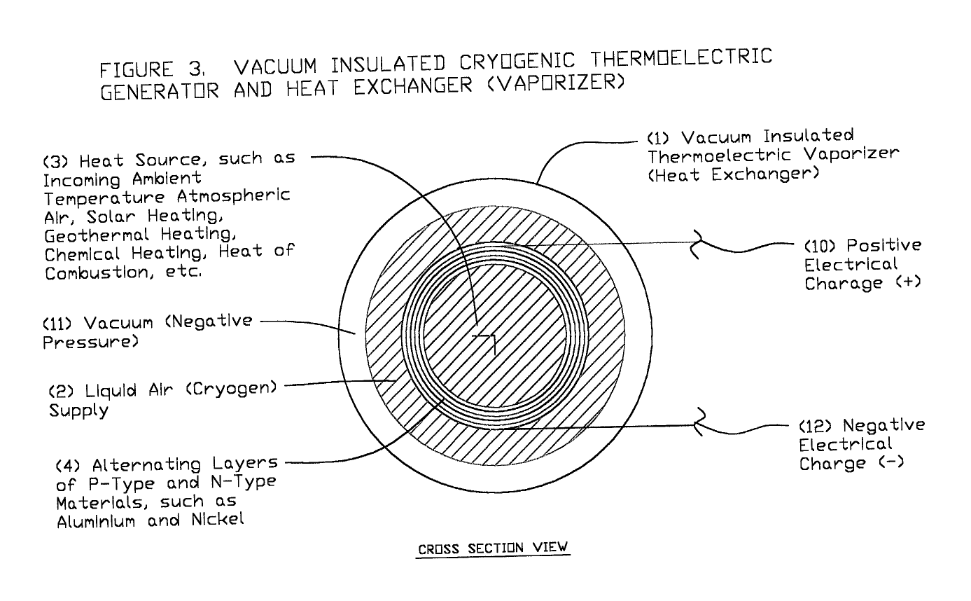

FIG. 3. describes a vacuum insulated (11) tubular shaped thermoelectric vaporizer (1) device that acts both as a cryogenic heat exchanger (vaporizer) and acts as a solid-state electric generator. A heat source (3) flows through the center of the thermoelectric vaporizer (1) and the heat source (3) is surrounded by alternating layers of p-type and n-type materials (4). A cryogen (2) surrounds the layers of materials (4) such that the layers of materials (4) are between the heat source (3) and the cryogen (2). The cryogen (2) that surrounds the layers of material (4) is surrounded by vacuum insulation (11) that prevents the ambient temperature of the atmosphere from reaching the thermoelectric vaporizer (1).

The alternating layers of p-type and n-type materials (4) generate a positive electrical current (10) and a negative electrical current (12) by converting a portion of the thermal energy from the heat source (3) into electricity.

Heat from the heat source (3) that is not converted to electricity is absorbed by cryogen (2) and the cryogen (2) becomes vaporized.

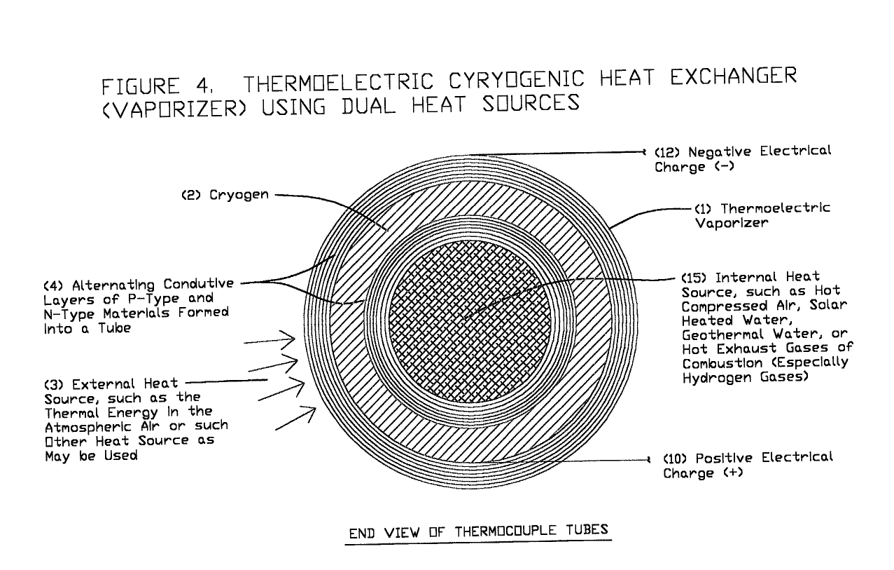

FIG. 4. describes a thermoelectric vaporizer (1), using an external heat source (3) and a separate inner heat source (15). The cryogen (2) and the two heat sources are separated by layers of p-type and n-type materials (4) that produce electricity. The atmosphere is the outer heat source (3) and the inner heat source (15) may be the heat of compression, solar heat, geothermal water, hot exhaust gases of combustion, or chemical heat, etc.

The inner heat source (15) flows through the center of the thermoelectric vaporizer (1) and is surrounded by layers of p-type and n-type materials (4). The layers of material (4) are surrounded by a cryogen (2) that is surrounded by a second set of layers of p-type and n-type materials (4), with the heat of the atmosphere surrounding the second set of layers of p-type and n-type materials (4).

The alternating layers of p-type and n-type materials (4) generate a positive electrical current (10) and a negative electrical current (12) by converting a portion of the thermal energy from the external heat source (3) and the inner heat source (15) into electricity. The heat from the external heat source (3) and the inner heat source (15) that is not converted to electricity is absorbed by the cryogen (2) and the cryogen (2) becomes vaporized.

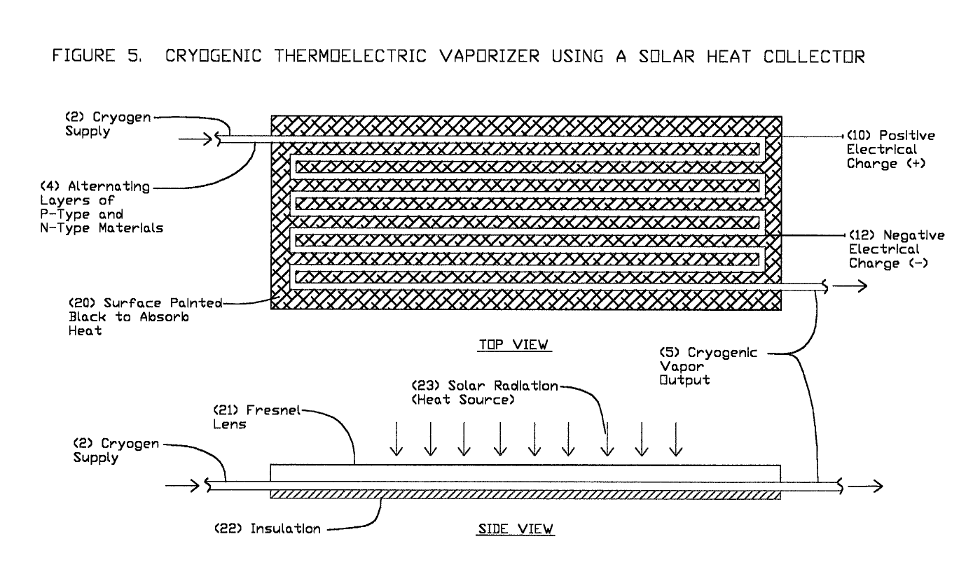

FIG. 5. describes a thermoelectric vaporizer (1) using a solar heat collector that is capable of vaporizing liquid air while it produces electricity. The apparatus may be located on the roof of a cryogenic vapor powered vehicle or may be used otherwise. Solar radiation (23) is concentrated by fresnel lens (21) over the top of the thermoelectric vaporizer (1) and the upper surface of the vaporizer (1) is painted black to absorb heat (20). The bottom of the thermoelectric vaporizer (1) is insulated (22) to keep heat from coming into contact with surfaces below the vaporizer (1). Tubes with cryogen (2) flowing within them are constructed of alternating layers of p-type and n-type materials (4) that generate a positive electrical current (10) and a negative electrical current (12) by converting a portion of the thermal energy from the solar radiation (23) which is a source of heat into electricity.

Heat from the solar radiation (23) that is not converted to electricity is absorbed by the cryogen (2) and the cryogen (2) becomes vaporized. The cryogenic vapor output (5) that is capable of performing mechanical work exits the thermoelectric vaporizer (1).

Although the present invention has been described by reference to only a few embodiments thereof, it is to be understood that many changes and modifications may be readily derived by those skilled in the art, and it is intended by the appended claims that the scope of this invention is intended to cover all changes, modifications, uses and all new embodiments of the present invention that are in the spirit and scope of the invention.

1. A thermoelectric vaporizer is hereby claimed:
It is claimed that the thermoelectric vaporizer is a thermoelectric heat exchanger.
It is claimed that liquid cryogen flows through the thermoelectric heat exchanger.
It is claimed that the thermoelectric vaporizer is capable of producing electricity thermoelectrically; and,
it is claimed that the thermoelectric vaporizer is simultaneously capable of vaporizing a liquid cryogen.

2. It is claimed that the thermoelectric vaporizer of claim 1 is constructed of electrically conductive and thermally conductive base materials, such as aluminum and nickel.
It is claimed that heat may conduct through the materials of which the thermoelectric vaporizer is constructed.
It is claimed that a portion of the heat conducting through the thermoelectric vaporizer is converted to electricity thermoelectrically.
It is claimed that a portion of the heat that conducts through the vaporizer is absorbed by the liquid cryogen; and,
it is claimed that the liquid cryogen is vaporized by the heat.

3. A thermoelectric solid-state generator is hereby claimed.
It is claimed that the thermoelectric vaporizer of claim 1 is a thermoelectric solid-state generator capable of producing electricity.
It is claimed that the thermoelectric vaporizer is constructed of alternate layers of p-type and n-type materials.
It is claimed that the materials are heat permeable.
It is claimed that the materials may be constructed in a tubular shape, a square shape, or in a rectangular shape.
It is claimed that heat penetrating the material generates an electric current as the heat is transformed into electricity at the p/n junctions.
It is claimed that the vaporizer may be used as a solid-state electric generator for use as a fixed-site electric power plant for the production of electricity for an electric power utility; and,
it is claimed that the vaporizer may be used for the vaporization of a cryogen that can perform mechanical work, having cryogenic liquid on one side of the vaporizer and atmospheric air as a heat source on the other side of the vaporizer; and,
it is claimed that the mechanical work may be used to produce a cryogen.

4. Energetic cryogenic vapor is hereby claimed.
It is claimed that the cryogenic vapor created by vaporization of the cryogen within the thermoelectric vaporizer of claim 1 absorbs thermal energy in the form of heat; and,
it is claimed that the internal energy of the cryogenic vapor is increased.
It is claimed that the energetic cryogenic vapor possesses substantial kinetic energy.
It is claimed that the energetic cryogenic vapor may power a rotary vane motor, gas expander, bladeless turbine, piston, or otherwise may produce mechanical drive.
It is claimed that the energetic cryogenic vapor may power a rotary vane motor, gas expander, bladeless turbine or other device to produce mechanical drive that can power a vehicle; and,
it is claimed that rotary vane motors built onto the axles of a vehicle may be powered by energetic cryogenic vapor to provide a drive force for the vehicle.
It is claimed that the energetic cryogenic vapor may power a rotary vane motor, gas expander, bladeless turbine or other device to produce mechanical drive that can produce liquid cryogen from air within the atmosphere.
The Applicant has filed a pending U.S. patent application titled, “Cryogen Production Via a Cryogenic Vapor Driven Power Piston for use in a Cryogenic Vapor Powered Vehicle with Rotary Vane Motors Attached to the Axles of the Vehicle next to the Vehicle's Four Wheels, Using a Heat Source such as Solar Heat, Heat of Compression (Heat Pump or Air Compressor, etc.) or Heat of Friction (as Formed by an Electric Generator) or Chemical Heat, or Heat Formed by Electrical Resistance, Heat of Combustion, etc. to Generate High-Pressure, High-Kinetic Energy Cryogenic Vapor”. The thermoelectric vaporizer that is the present invention of this patent application is used within the cryogenic vapor powered vehicle of the above pending patent application to generate electricity and to vaporize the cryogen produced and to perform work with the energetic cryogenic vapor, including the production of liquid cryogen from air in the atmosphere.

5. A thermoelectric vaporizer using multiple sources of heat is hereby claimed.
It is claimed that the thermoelectric vaporizer may use an external heat source and one or more separate inner heat sources.
It is claimed that the cryogen and the heat sources are separated by layers of p-type and n-type materials that produce electricity.

6. A thermoelectric vaporizer formed in a tubular shape is hereby claimed.
It is claimed that the thermoelectric vaporizer may be constructed as an assembly of tubular shapes; and,
It is claimed that the tubes are constructed of electrically conductive layers of p-type and n-type materials capable of converting heat into electricity; and,
It is claimed that the layers of material are also thermally conductive; and,
It is claimed that heat may conduct through the tubular shaped layers of materials to vaporize a cryogen.

7. A thermoelectric vaporizer formed in a square or in a rectangular shape is hereby claimed.
It is claimed that a thermoelectric vaporizer may be shaped in a square shape or in a rectangular shape constructed of stacks of electrically conductive layers of p-type and n-type materials capable of converting heat into electricity; and,
It is claimed that the layers of material are also thermally conductive; and,
It is claimed that heat may conduct through the stacks of layers of p-type and n-type materials to vaporize a cryogen.
It is claimed that the direction of heat is parallel to the p/n junctions, thus providing more opportunities for the production of electricity as the heat moves along the junctions.
It is further claimed that an alternating current is provided that can prevent cold spot formation and thus prevent loss of efficiency of electricity formation.
It is claimed that the stack of layers of p-type and n-type materials have alternating layers of heat on one side of a stack of layers and a cryogen on the other side of the stack of layers to form an assembly with vacuum insulation surrounding the assembly.
It is claimed that heat sources such as the thermal heat from the atmosphere, solar heat, geothermal heat, chemically produced heat, heat of combustion, heat of compression of air, heat of friction, etc. may be used in the thermoelectric vaporizer.

8. Vacuum insulation is hereby claimed.
It is claimed that vacuum insulation may prevent the loss of cold or heat from the thermoelectric vaporizer of claim 7 to the atmosphere.
It is claimed that the vacuum insulation prevents the ambient temperature of the atmosphere from reaching the cryogen or the heat source within the thermoelectric vaporizer of claim 7.

9. A solar heated thermoelectric vaporizer is hereby claimed.
It is claimed that a cryogenic vaporizer and thermoelectric generator may use the direct heat of the sun as a source of heat to vaporize the cryogen and to produce electricity thermoelectrically.
It is claimed that a solar collector contains a thermoelectric vaporizer with a cryogen flowing through the center of the vaporizer.
It is claimed that the walls of the vaporizer are tubular shaped and are formed of p-type and n-type materials in alternating layers capable of producing electricity from heat.
It is claimed that solar heat is applied to the vaporizer via a fresnel lens the top of the vessel.
It is claimed that the thermoelectric vaporizer is painted black to absorb heat.
It is claimed that heat may conduct through the layers of p-type and n-type materials to vaporize a cryogen.
